(19) United States
(12) Patent Application Publication
(10) Pub. No.: US 2024/0422955 A1
(43) Pub. Date: Dec. 19, 2024

(54) FEEDER MOVEMENT ASSISTANCE SYSTEM AND FEEDER STAND

(71) Applicant: FUJI CORPORATION, Chiryu (JP)

(72) Inventor: Satoshi SHIOYA, Okazaki-shi (JP)

(73) Assignee: FUJI CORPORATION, Chiryu (JP)

(21) Appl. No.: 18/706,467

(22) PCT Filed: Nov. 25, 2021
(86) PCT No.: PCT/JP2021/043121

§ 371 Date: May 1, 2024

(51) Int. Cl. H05K 13/02

(52) U.S. Cl. CPC H05K 13/02

(57) ABSTRACT

A feeder movement assistance system includes multiple storage side display sections to display the storage position in a display manner selected from multiple display manners, a storage section configured to store the tape feeder, multiple movement destination display sections provided in multiple movement destination devices as candidates to which the tape feeder is to be moved, and a display control section configured to cause the storage side display section indicating the storage position of the tape feeder to be moved and the movement destination display section in the movement destination device to which the tape feeder is to be moved to perform a display in a corresponding display manner, based on a storage content of the storage section and a content of a movement request, when the movement request for moving the tape feeder stored in the feeder stand to any of the multiple movement destination devices is generated.

### TECHNICAL FIELD

The present description relates to a feeder movement assistance system that assists movement work of a tape feeder, and a feeder stand.

### BACKGROUND ART

A technique for mass-producing board products by performing board work on a board on which a circuit pattern is formed is widespread. In a normal board production factory, a board production line formed by arranging multiple types of board work machines is installed. As a representative example of a board work machine, there is a component mounter that performs mounting work of a component. Many component mounters use a tape feeder that pulls out and feeds a carrier tape that accommodates multiple components from a reel. The tape feeder includes an integral type for holding the reel and a separate type for separately placing the reel. When the carrier tape is used up to the end as the mounting work progresses, the integrated tape feeder does not exchange the reel, but exchanges the entire tape feeder to replenish components.

In addition, in setup exchange operation when changing the type of board product to be produced, the considerable number of types of components supplied from the tape feeder are often changed. In this case, multiple tape feeders or reels are collectively exchanged. In order to increase the efficiency of the collective exchange operation, a component supply device having a wheeled platform shape detachably provided in the component mounter is used. The preparation work for equipping multiple tape feeders in the component supply device is performed in advance in an external setup area. In the board production factory, a large number of tape feeders are combined in various manners with respect to multiple component supply devices, and are used compatibly with multiple component mounters. Patent Literatures 1 and 2 disclose examples of techniques for increasing the efficiency of tape feeder exchange operation and movement work.

In a feeder exchange assistance system disclosed in Patent Literature 1, in a case where there are multiple feeders (tape feeders) that need to be exchanged in a component mounter at the same time, a display manner of a display section is changed for each combination so that an operator can recognize the combination of a feeder to be removed and a feeder for exchange. Specifically, the display manner of a feeder exchange position indicator of the component mounter and the display manner of an indicator of a feeder preparation wheeled platform are changed for each combination. For example, a display method of changing the lighting time or the extinguishing time of the intermittent lighting of the indicator or changing the blinking cycle is used. In addition, it is also described that a feeder installation shelf or the like may be used instead of the feeder preparation wheeled platform. Accordingly, the operator can easily know the positions of the feeder to be removed and the feeder for exchange by viewing the display on both the component mounter side and the preparation wheeled platform side, and the exchange operation is simplified.

In addition, a setup assistance device disclosed in Patent Literature 2 includes a preparation wheeled platform on which multiple feeders are loaded, an identification device that acquires identification information of a component supply device of a component mounter, a feeder specifying section that specifies multiple feeders to be set in the component supply device from the preparation wheeled platform based on the identification information of the component supply device, loading information of the preparation wheeled platform, and a production schedule, and a guide section that collectively guides the specified multiple feeders. Accordingly, the operator can easily recognize the feeder set in the component supply device among multiple feeders loaded on the preparation wheeled platform, and can efficiently and accurately perform the setup of the component mounter.

### PATENT LITERATURE

Patent Literature 1: JP-A-2016-18968
Patent Literature 2: WO2018/092249

### SUMMARY OF THE INVENTION

### Technical Problem

Incidentally, in the configurations of Patent Literatures 1 and 2, it is preferable to selectively display (guide) a feeder necessary for exchange and mounting among a large number of feeders on the feeder preparation wheeled platform or the feeder installation shelf. However, in a case where the feeder preparation wheeled platform or the feeder installation shelf is disposed away from the component mounter, the operator cannot directly view the detailed display on the component mounter side, and may hesitate about where to take the feeder necessary for exchange and mounting (movement destination).

More specifically, there are many configurations in which multiple board production lines are installed in a board production factory, and not only one component mounter but also multiple component mounters are arranged in one board production line. The feeder preparation wheeled platform is commonly used for multiple component mounters. Therefore, even when the operator beside the feeder preparation wheeled platform can take out, from the wheeled platform, the feeder to be moved while he/she views the display on the wheeled platform side, the operator cannot view the detailed display of the component mounter, which is the movement destination, from a distance. Eventually, the operator needs to check the movement destination of the feeder by viewing a guide screen or the like of a personal computer constituting the feeder exchange assistance system or the setup assistance device, and the work efficiency of the movement work is reduced.

Therefore, an object of the present description is to provide a feeder movement assistance system and a feeder stand capable of increasing the efficiency of the movement work of a tape feeder by displaying a position of a movement source of the tape feeder and a movement destination device in association with each other.

### Solution to Problem

According to an aspect of the present description, there is provided a feeder movement assistance system including multiple storage side display sections disposed corresponding to multiple storage positions of a feeder stand storing multiple tape feeders, respectively and configured to perform a display indicating the storage position in a display manner selected from multiple display manners, a storage section configured to store the tape feeder stored in the feeder stand and the storage position in association with each other, multiple movement destination display sections provided in multiple movement destination devices as candidates to which the tape feeder is to be moved, respectively and configured to perform a display in the display manners which are different from each other, and a display control section configured to cause the storage side display section indicating the storage position of the tape feeder to be moved and the movement destination display section provided in the movement destination device to which the tape feeder is to be moved to perform a display in a corresponding display manner, based on a storage content of the storage section and a content of a movement request, in a case where the movement request for moving the tape feeder stored in the feeder stand to any of the multiple movement destination devices is generated.

In addition, according to another aspect of the present description, there is provided a feeder stand including multiple storage positions where tape feeders are stored, respectively, multiple storage side display sections disposed corresponding to the multiple storage positions, respectively and configured to perform a display indicating the storage position in a display manner selected from multiple display manners, a storage section configured to store a correspondence relationship between the stored tape feeder and the storage position, and the display manners different from each other and set in multiple movement destination devices as candidates to which the tape feeder is to be moved, respectively and a display control section configured to display the display manner of the storage side display section indicating the storage position of the tape feeder to be moved in association with the display manner set in the movement destination device to which the tape feeder is to be moved, based on a storage content of the storage section and a content of a movement request, in a case where the movement request for moving the stored tape feeder to any one of the multiple movement destination devices is generated.

### Advantageous Effect of the Invention

In the disclosed feeder movement assistance system, the display control section cause the storage side display section indicating the storage position of the tape feeder moved from the feeder stand and the movement destination display section provided in the movement destination device to which the tape feeder is to be moved to perform a display in the corresponding display manner. In addition, in the disclosed feeder stand, the display control section displays the display manner of the storage side display section indicating the storage position of the tape feeder to be moved in association with the display manner set in the movement destination device. The operator who has viewed the display can check the correspondence relationship between the position of the movement source of the tape feeder and the movement destination device, and thus can efficiently perform the movement work without making a mistake in the tape feeder, and without becoming lost in the movement destination. Accordingly, the disclosed feeder movement assistance system and the disclosed feeder stand can increase the efficiency of the movement work of the tape feeder.

### BRIEF DESCRIPTION OF DRAWINGS

FIG. 1 is a perspective view illustrating a configuration example of an actual feeder stand.

FIG. 2 is a front view schematically illustrating a configuration of the feeder stand of an embodiment in which the number of tape feeders that can be stored is reduced as compared with the configuration example of FIG. 1.

FIG. 3 is a perspective view schematically illustrating a configuration example of a board production line using the tape feeder.

FIG. 4 is an overall configuration diagram schematically illustrating a feeder movement assistance system of the first embodiment including the feeder stand.

FIG. 5 is a diagram illustrating an operation of the feeder movement assistance system according to the first embodiment.

FIG. 6 is a table of a screen display example of a screen display device.

FIG. 7 is a plan view schematically illustrating a configuration example of a component mounter using the tape feeder.

FIG. 8 is a diagram schematically illustrating a configuration of a feeder movement assistance system according to a second embodiment and illustrating the operation.

FIG. 9 is a diagram schematically illustrating a configuration of a feeder movement assistance system according to a third embodiment and illustrating the first half of the operation.

FIG. 10 is a diagram illustrating a latter half of the operation of the feeder movement assistance system according to the third embodiment.

### DESCRIPTION OF EMBODIMENTS

### 1. Actual Feeder Stand 1A

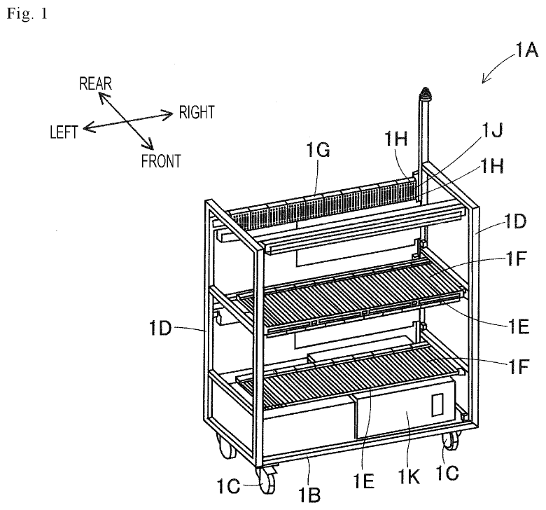

Before describing feeder stand 1 of the embodiment, a configuration example of actual feeder stand 1A will be described with reference to FIG. 1. Feeder stand 1A stores a tape feeder used in a component mounter. As indicated by the upper left arrow in FIG. 1, the front, rear, left, and right of feeder stand 1A are defined for convenience. Feeder stand 1A is formed in a substantially rectangular parallelepiped shape having a width dimension and a height dimension larger than a depth dimension. Feeder stand 1A includes bottom plate 1B, four pillar materials 1D, two upper and lower shelf plates 1E, two rear surface plates 1G, and stand control section 1K.

Bottom plate 1B is a member having a rectangular plate shape, and is disposed horizontally close to a floor surface. Caster 1C for movement is provided at four corners of the lower surface of bottom plate 1B, respectively. Pillar material 1D directed upward is erected at four corners of the upper surface of bottom plate 1B, respectively. Two upper and lower shelf plates 1E are horizontally extended to intermediate heights of four pillar materials 1D. Each of shelf plates 1E has a rectangular plate shape and has 50 slots 1F. Slots 1F have recessed groove shapes extending in the front-rear direction and are parallel to each other. An operator can insert a tape feeder into each slot 1F from the front side and store the tape feeder. In addition, the operator can pull out and take out the tape feeder stored in slot 1F to the front side. Slot 1F is one aspect of a storage position where the tape feeder is stored.

Two rear surface plates 1G are provided at the rear upper portions of two shelf plates 1E. Each of rear surface plates 1G is formed in an elongated rectangular plate shape having a small height dimension and a large width dimension in the left-right direction, and is vertically disposed. Each of rear surface plates 1G has 50 sets of positioning sections 1H and electrical connection sections 1J at the position corresponding to each of slots 1F. Positioning section 1H is separately disposed above and below electrical connection section 1J. Each of positioning section 1H is, for example, a pair of upper and lower positioning holes into which a pair of upper and lower positioning pins provided on the rear surface of the tape feeder are inserted. Positioning section 1H determines the position of the tape feeder inserted into slot 1F and stabilizes the position of the tape feeder in the storage state.

Each of electrical connection sections 1J is, for example, a recessed connector into which a projected connector provided on the rear surface of the tape feeder is fitted. Electrical connection section 1J is automatically fitted in synchronization with the positioning by positioning section 1H. Electrical connection section 1J supplies power to a tape feeder to be stored and enables communication connection to a feeder control section in the tape feeder.

Stand control section 1K is disposed between lower shelf plate 1E and bottom plate 1B. Stand control section 1K is configured using a computer device. Stand control section 1K is communicably connected to the feeder control section in the stored tape feeder by the fitting of electrical connection section 1J. As a result, various data are exchanged between stand control section 1K and the feeder control section.

Actual feeder stand 1A can store 50 units of tape feeders for each of shelf plates 1E, and up to 100 units of tape feeders in total. In addition, feeder stand 1A supplies power to the stored tape feeder and is capable of exchanging data. Furthermore, since feeder stand 1A includes casters 1C, feeder stand 1A can be moved by an operation of the operator. That is, feeder stand 1A can move to a storage area, an external setup area, a board production line, and the like in the board production factory.

### 2. Feeder Stand 1 of Embodiment

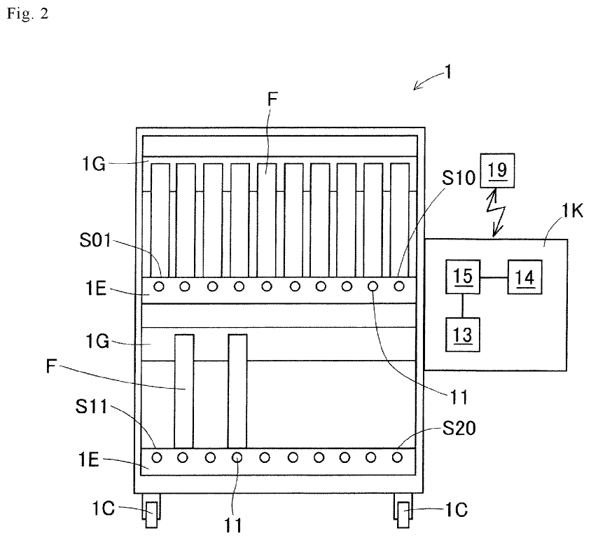

In order to simplify the following description, an example of feeder stand 1 according to the embodiment in which the number of sets of slot 1F is reduced to 20 sets will be described with reference to FIG. 2. In FIG. 2, the positions of ten slots 1F of upper shelf plate 1E are subsequently defined as S01 to S10 from the left side to the right side. In addition, the positions of ten slots 1F of lower shelf plate 1E are subsequently defined as S11 to S20 from the left side to the right side. According to this determination, in FIG. 2, a total of twelve tape feeders F are stored in slots 1F at positions S01 to S10, position S12, and position S14 of feeder stand 1.

Tape feeder F uses a carrier tape containing multiple components. Tape feeder F has a reel holding section that rotatably holds a reel around which a carrier tape is wound, and a supply position at which a component is supplied. Tape feeder F supplies the component by drawing out the carrier tape from the reel and sending the carrier tape to the supply position. Tape feeder F has a ridge to be fitted into slot 1F on the bottom.

Feeder stand 1 includes multiple storage side display sections 11 and screen display device 19 is attached, in addition to the configuration of feeder stand 1A described above. Multiple storage side display sections 11 are disposed corresponding to each of slots 1F. Specifically, storage side display section 11 is disposed on the lower side of slots 1F on the front surfaces of upper and lower shelf plates 1E. Accordingly, the number of storage side display sections 11 matches the number of slots 1F, in other words, is 20, which is equal to the maximum number of tape feeders F that can be stored.

Storage side display section 11 performs display indicating slot 1F in a display manner selected from multiple display manners. In the present embodiment, storage side display section 11 is a light source that can selectively light any one of multiple colors as multiple display manners. Specifically, a multicolor light source capable of selectively lighting seven colors can be used as storage side display section 11. The multicolor light source has three types of monochromatic LED light sources that emit light of each of three primary colors, and adjusts the luminance of these monochromatic LED light sources to generate one of seven colors. The configuration is not limited to this, and Storage side display section 11 may selectively light any one of multiple monochromatic light sources capable of emitting light of different colors.

In addition, storage side display section 11 can use the color and the blinking manner of the light source in combination as the display manner. For example, in addition to the seven colors described above, when three types of continuous lighting of the light source, blinking with a short repetition cycle, and blinking with a long repetition cycle are used in combination, storage side display section 11 has 21 types (=7×3) of display manners in total. In the blinking manner, the number of types of display manners can be increased by changing the ratio (duty ratio) of the lighting time even when the repetition cycle of the blinking is constant.

Stand control section 1K includes three functional units configured using software, that is, storage section 13, request reception section 14, and display control section 15. Storage section 13 stores stored tape feeder F and the position (S01 to S20) of slot 1F in association with each other. Specifically, storage section 13 first acquires any of the following codes (A), (B), and (C) or multiple codes stored in the feeder control section through communication with the feeder control section in tape feeder F.
(A) Feeder identification code for identifying tape feeder F
(B) Reel identification code for identifying reels held by tape feeder F
(C) Component type identification code for identifying the type of component supplied by tape feeder F

Next, storage section 13 stores the position (S01 to S20) of slot 1F corresponding to the position of electrical connection section 1J used for communication with the feeder control section in association with the acquired code. Normally, components used by the component mounter for mounting work are often managed by the component type identification code. In this case, storage section 13 may perform storage using the above (C). However, tape feeders F and reels used in the component mounter may be reserved in advance, or the order in which the reels are used may be restricted. In this case, storage section 13 needs to perform storage using the above (A) or (B).

In addition, storage section 13 may acquire and store predetermined association data by means other than communication with tape feeder F. For example, the operator may operate a handy scanner attached to feeder stand 1 to acquire the code displayed on tape feeder F or the reel stored in slot 1F and transfer the code to storage section 13. In addition, in a configuration in which electrical connection section 1J is omitted, predetermined association data may be transferred from another device to stand control section 1K. As another device, there is a feeder management device or the like that instructs slot 1F of tape feeder F to be stored for the operator.

Request reception section 14 receives a movement request for moving tape feeder F stored in feeder stand 1 to a movement destination device (described later). The movement request is input from the outside of feeder stand 1. Display control section 15 controls the display of multiple storage side display sections 11 based on the storage content of storage section 13 and the contents of the movement request. That is, display control section 15 performs switching control of lighting and extinguishing of multiple storage side display sections 11, respectively and selection control of color to be lit. Furthermore, in a case where storage side display section 11 uses the blinking manner in combination, display control section 15 performs switching control of multiple types of blinking manners of storage side display section 11.

Screen display device 19 displays the contents of the display data edited by display control section 15 on the screen. In the present embodiment, screen display device 19 is a mobile terminal carried by the operator. Screen display device 19 including a mobile terminal receives display data from stand control section 1K which is wirelessly communicably connected. Screen display device 19 may be used in common with other applications, and for example, may also be used for displaying the operating status of the board production line, and the like.

Screen display device 19 is not limited to the mobile terminal described above, and various devices having a screen display function and communicably connected to stand control section 1K in a wired or wireless manner can be applied. A part or all of the functions of stand control section 1K may be provided in a control device separate from feeder stand 1. The functions of request reception section 14, display control section 15, and screen display device 19 will be described in detail later.

### 3. Configuration Example of Board Production Line 9

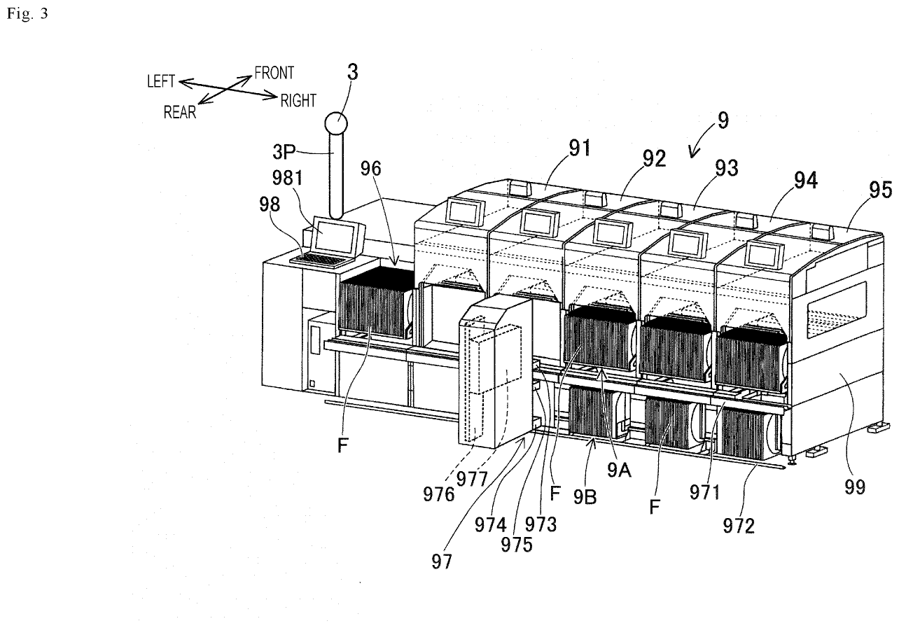

Next, a configuration example of board production line 9 using tape feeder F will be described with reference to FIG. 3. As indicated by the upper left arrow in FIG. 3, the front, rear, left, and right of board production line 9 are defined for convenience. Board production line 9 is formed by arranging the multiple board work machines in the left-right direction. That is, solder printer 91, printing inspection machine 92, first component mounter 93, second component mounter 94, third component mounter 95, a board visual inspection machine (not illustrated), and a reflow machine (not illustrated) are arranged from the left side (upstream) to the right side (downstream). The direction from the left side to the right side is the board conveyance direction.

The board work machines perform a predetermined work on the board, that is, the board work, respectively. More specifically, solder printer 91 prints paste solder on the board in a predetermined pattern shape. Printing inspection machine 92 captures an image and inspects the solder printing state on the board. First component mounter 93, second component mounter 94, and third component mounter 95 pick up the component from tape feeder F and mount the component on the solder printed on the board. The board visual inspection machine captures an image of the component mounted on the board and inspects the mounting state. The reflow machine heats and remelts the solder, and further cools and solidifies the solder to ensure the soldered state of the component.

First component mounter 93, second component mounter 94, and third component mounter 95 have the same structure. The component mounter (93, 94, and 95) is formed by assembling device pallet 9A, replenishment pallet 9B, a board conveyance device not visible in FIG. 3, a component transfer device, a control device (not illustrated), and the like to base 99.

Device pallet 9A is disposed at a substantially intermediate height on the front side of base 99. Device pallet 9A functions as a component supply device. Device pallet 9A has the same configuration as slot 1F, positioning section 1H, and electrical connection section 1J of feeder stand 1A. Tape feeder F is inserted and set in each slot of device pallet 9A from the front side. Tape feeder F can be used compatibly with first component mounter 93, second component mounter 94, and third component mounter 95. Device pallet 9A may further allow multiple types of tape feeders F having different width dimensions in the left-right direction and internal structures to be used in a mixed manner.

Replenishment pallet 9B is disposed below device pallet 9A on the front side of base 99. Replenishment pallet 9B has the same configuration as slot 1F, positioning section 1H, and electrical connection section 1J of feeder stand 1A. Replenishment pallet 9B stores, in each slot, used tape feeder F, tape feeder F for exchange and attachment used by replacing used tape feeder F, and the like. The number of slots of replenishment pallet 9B is the same as that of device pallet 9A, but may be different.

The board conveyance device carries in, positions, and carries out the board. The component transfer device picks up the component from tape feeder F on device pallet 9A using the suction nozzle, and mounts the component on the solder printed on the board. The control device causes tape feeder F, the board conveyance device, and the component transfer device based on the work data to advance the component mounting work. The control device is formed by using a computer device, or is formed by multiple computer devices distributed and disposed in the component mounter (93, 94, and 95) being communicably connected.

Board production line 9 is further provided with feeder buffer 96, feeder conveyance device 97, line management device 98, and movement destination display section 3. Feeder buffer 96 is provided adjacent to the left side of solder printer 91. Feeder buffer 96 temporarily holds tape feeder F moved from feeder stand 1. Feeder buffer 96 is disposed at the same height as that of device pallet 9A of component mounters (93, 94, and 95). Feeder buffer 96 has the same configuration as slot 1F, positioning section 1H, and electrical connection section 1J of feeder stand 1A. Tape feeder F is inserted and set in each slot of feeder buffer 96 from the front side.

Feeder conveyance device 97 attaches, detaches, and conveys tape feeder F among device pallet 9A, replenishment pallet 9B, and feeder buffer 96. Feeder conveyance device 97 is formed in a vertically long box shape with an open rear side. Feeder conveyance device 97 is provided to be movable in the left-right direction along a trajectory portion provided on the front side of three component mounters (93, 94, and 95) and feeder buffer 96.

Middle-level rail 971 and lower-level rail 972 corresponding to the trajectory portion are provided on the front surface of base 99 of the multiple board work machines and the front surface of feeder buffer 96, respectively. Middle-level rail 971 and lower-level rail 972 extend in the left-right direction. The height position of middle-level rail 971 is unified at an intermediate height between device pallet 9A and replenishment pallet 9B. The height position of lower-level rail 972 is unified to the height of the lower portion of replenishment pallet 9B. As a result, multiple middle-level rails 971 and multiple lower-level rails 972 form two trajectory portions which are parallel to each other and continue from feeder buffer 96 to third component mounter 95.

Meanwhile, feeder conveyance device 97 includes middle-level traveling section 973 and lower-level traveling section 974 on the rear side thereof. Middle-level traveling section 973 is travelably engaged with middle-level rail 971. Lower-level traveling section 974 is travelably engaged with lower-level rail 972. Middle-level traveling section 973 further includes a driving source that generates power for traveling, for example, a motor that drives traveling wheels. As a result, feeder conveyance device 97 is mounted on middle-level rail 971 and lower-level rail 972, and travels and moves in the left-right direction.

Furthermore, feeder conveyance device 97 includes non-contact power receiving section 975 at a height position between middle-level traveling section 973 and lower-level traveling section 974, which does not interfere with the attachment and detachment of tape feeder F. Non-contact power receiving section 975 receives power in a non-contact manner from non-contact power transmission sections (not illustrated) provided at a corresponding height on the multiple board work machines. As a result, the power consumption in feeder conveyance device 97 is covered.

In addition, feeder conveyance device 97 includes lifting and lowering drive section 976 and exchange section 977 inside a box-shaped interior. Lifting and lowering drive section 976 drives exchange section 977 to lift and lower from the height of device pallet 9A to the height of replenishment pallet 9B. As lifting and lowering drive section 976, a ball screw feeding mechanism may be exemplified: however, the configuration is not limited to this.

Exchange section 977 has an internal space that accommodates one or multiple tape feeders F. In addition, exchange section 977 includes a feeder attaching/detaching mechanism (not illustrated). The feeder attaching/detaching mechanism sets tape feeder F accommodated in the internal space on the pallet by driving tape feeder F rearward. In addition, the feeder attaching/detaching mechanism pulls out tape feeder F from the pallet and accommodates tape feeder F in the internal space by driving tape feeder F set in the pallet forward. The pallet described above means device pallet 9A, replenishment pallet 9B, and feeder buffer 96 described above. The applicant of the present application discloses a detailed configuration example of exchange section 977 in WO 2019/239475.

Line management device 98 is disposed adjacent to the left side of feeder buffer 96. Line management device 98 is formed by using a computer device. Line management device 98 is communicably connected to the control devices of the multiple board work machines. Line management device 98 manages work data describing work contents of the board works which are different for each board type. Line management device 98 sends the each of pieces of work data to the control devices of the multiple board work machines based on the board production plan.

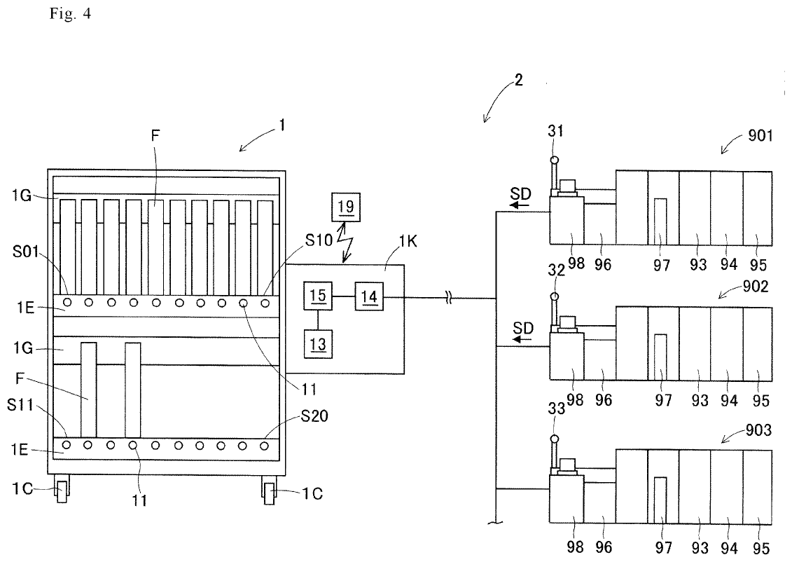

Furthermore, line management device 98 monitors the operation statuses of the multiple board work machines. In a case where tape feeder F of any one of the component mounters (93, 94, and 95) runs out of the component, line management device 98 causes feeder conveyance device 97 to exchange tape feeder F to replenish the component. Furthermore, in a case where the number of usable tape feeders F decreases and a movement request to move new tape feeder F to feeder buffer 96 is generated, line management device 98 displays the contents of the movement request on screen display section 981. In addition, line management device 98 outputs movement request signal SD (refer to FIG. 4) including the contents of the movement request.

Here, the contents of the movement request include at least one code of (A), (B), and (C) described above. The operator inserts tape feeder F matching the movement request into the slot of feeder buffer 96 according to the display on screen display section 981. Thereafter, by the operations of line management device 98 and feeder conveyance device 97, tape feeder F is conveyed to and attached to component mounters (93, 94, and 95) as necessary, and the components are automatically replenished.

Since tape feeders F for exchange and attachment can be prepared in advance in replenishment pallet 9B and feeder buffer 96, board production line 9 can deal with the shortage of components in an unmanned manner. In addition, the production interruption time when the component shortage occurs can be shortened. Furthermore, instead of moving one tape feeder F every time a component shortage occurs, multiple tape feeders F approaching the required timing can be collectively moved in advance, and thus the efficiency of the movement work is high.

Movement destination display section 3 is provided behind line management device 98. Movement destination display section 3 is disposed at a high position using support pole 3P, and is easily viewed by an operator from a distance. Support pole 3P is not essential, and movement destination display section 3 may be provided in another manner that is easy to view from a distance. Movement destination display section 3 is a light source capable of lighting a specific color. Specifically, a multicolor light source that is capable of selectively lighting the same seven colors as those of storage side display section 11 and lights in one specific color at any time, or a monochromatic light source can be applied to movement destination display section 3. Movement destination display section 3 lights only when the movement request is generated, and clearly displays the necessity of the movement work of tape feeder F. The configuration is not limited to this, and movement destination display section 3 may be constantly lit.

Furthermore, movement destination display section 3 can use a blinking manner of the light source in combination in addition to switching between lighting and extinguishing. Movement destination display section 3 is controlled by line management device 98. In addition, movement destination display section 3 may be a placard that displays a specific color, in other words, a thing (one display manner) that displays only a specific color that does not require control.

### 4. Feeder Movement Assistance System 2 of First Embodiment

Next, a configuration and operation of feeder movement assistance system 2 of the first embodiment will be described with reference to FIGS. 4 to 6. Feeder movement assistance system 2 includes feeder stand 1 and movement destination display sections (31, 32, and 33) provided in the multiple board production lines, respectively. First board production line 901, second board production line 902, and third board production line 903 which are specific examples of the multiple board production lines correspond to the multiple movement destination devices which are candidates to which tape feeder F is to be moved. Movement destination display sections (31, 32, and 33) of each of the board production lines perform display in the display manners which are different from each other.

Specifically, display in yellow is assigned to movement destination display section 31 of first board production line 901, display in blue is assigned to movement destination display section 32 of second board production line 902, and display in red is assigned to movement destination display section 33 of third board production line 903. Storage section 13 of feeder stand 1 stores different display manners set for the multiple movement destination devices, respectively. That is, storage section 13 stores three colors assigned to each of the board production lines and different from each other in association with the line numbers (first to third).

In a case where storage side display section 11 is a multicolor light source capable of selectively lighting seven colors, in other words, has seven types of display manners, in feeder movement assistance system 2, the board production lines up to seven lines, which are equal to the number of types of display manners, serve as application targets. In a case where storage side display section 11 can selectively light seven colors and has 21 types of display manners in combination with the blinking manner, in feeder movement assistance system 2, the board production lines up to 21 lines serve as application targets. In addition, feeder movement assistance system 2 causes simultaneous use of multiple feeder stands 1 (for example, use feeder stand A and feeder stand B in combination).

Feeder stand 1 is disposed away from the board production line on the condition that feeder stand 1 can be communicably connected. For example, feeder stand 1 is disposed in the external setup area and is connected to the board production line via a work management device installed in the external setup area. As illustrated in FIG. 4, request reception section 14 of feeder stand 1 is communicably connected to line management device 98 of each of the board production lines. Request reception section 14 receives movement request signal SD output from each of line management devices 98. In a case where multiple feeder stands 1 are used, request reception sections 14 receive movement request signal SD independently and separately, respectively.

Hereinafter, the operation of feeder movement assistance system 2 will be described using, as an example, a case where the system configuration includes one feeder stand 1, movement request signal SD is output from first board production line 901, and then movement request signal SD is output from second board production line 902. Request reception section 14 first receives movement request signal SD of first board production line 901. Movement request signal SD is not limited to the case where there is only one tape feeder F to be moved, but may be the case where there are multiple tape feeders F to be moved. Request reception section 14 transfers the fact that movement request signal SD is received and the contents of movement request signal SD to display control section 15.

Display control section 15 first obtains the storage position where tape feeder F to be moved is stored based on the storage content of storage section 13 and the contents of the movement request. That is, display control section 15 searches the storage content of storage section 13 using at least one code of (A), (B), and (C) included in movement request signal SD, obtains tape feeder F having the same code, and obtains the storage position (position of slot 1F) in which tape feeder F is stored. Here, it is assumed that the positions are position S01 and position S03. In a case where there is no tape feeder F having the same code, display control section 15 transmits the fact to screen display device 19 to display the fact on the screen.

Next, display control section 15 causes storage side display section 11 indicating position S01 and position S03, and movement destination display section 31 provided in first board production line 901 as the movement destination to perform a display in the corresponding display manners. In other words, display control section 15 displays the display manner of storage side display section 11 indicating position S01 and position S03, which are the storage positions of tape feeder F to be moved, in association with the display manner set on movement destination display section 31 provided in first board production line 901 as the movement destination.

The corresponding display manner means the display in yellow assigned to first board production line 901. That is, display control section 15 lights two storage side display sections 11 indicating position S01 and position S03 in yellow. Simultaneously, display control section 15 transmits lighting request signal SL to line management device 98 of first board production line 901. Line management device 98 which has received lighting request signal SL lights movement destination display section 31 in yellow (the same color as storage side display section 11).

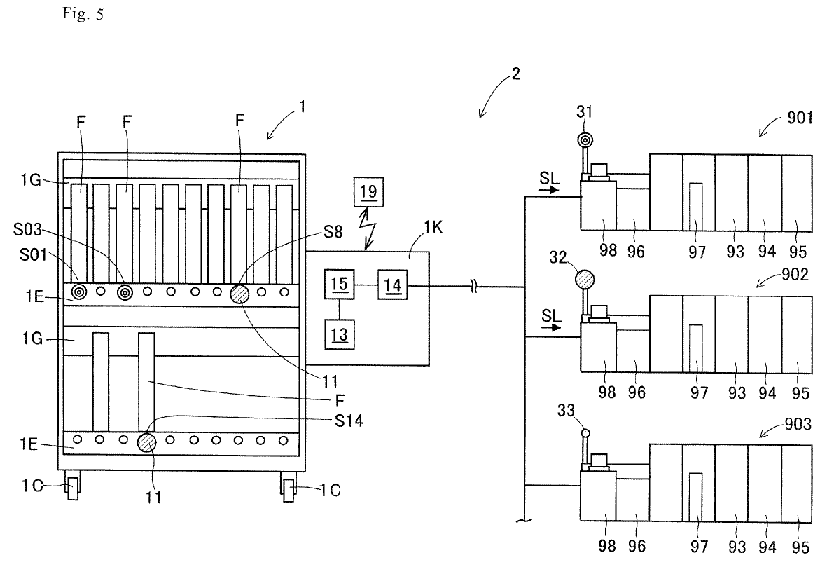

In FIG. 5, storage side display section 11 and movement destination display sections (31 and 32) to be lit are illustrated using large circles for easy viewing, for convenience. In addition, the lighting of storage side display section 11 and movement destination display section 31 in yellow is indicated by a triple circle, and the lighting of storage side display section 11 and movement destination display section 32 in blue is indicated by a circle with oblique hatching. The operator who views the lighting in yellow can easily confirm the correspondence relationship between position S01 and position S03 at which tape feeder F is pulled out, and first board production line 901 which is the movement destination. At this time, since movement destination display section 31 is disposed at a high and easily viewable position, even the operator from a distance can confirm movement destination display section 31 by direct viewing. Conversely, in the technique of Patent Literature 1, since the movement destination is displayed using the indicator provided in device pallet 9A of the component mounter (93, 94, and 95), the operator from a distance cannot directly view the display.

Control of display control section 15 described above is similarly executed in response to movement request signal SD from second board production line 902. It is assumed that the positions of tape feeder F moved to second board production line 902 are position S08 and position S14. Display control section 15 lights two storage side display sections 11 indicating position S08 and position S14 in blue, and simultaneously transmits lighting request signal SL to line management device 98 of second board production line 902. Line management device 98 which has received lighting request signal SL lights movement destination display section 32 in blue. The operator who views the lighting in blue can easily confirm the correspondence relationship between position S08 and position S14 at which tape feeder F is pulled out, and second board production line 902 which is the movement destination.

In this manner, display control section 15 causes multiple storage side display sections 11 and one or more movement destination display sections (31 and 32) to simultaneously perform a display so as to correspond to multiple tape feeders F to be moved. The operator can pull out four tape feeders F from feeder stand 1 based on four storage side display sections 11 which are lit, and move tape feeders F to first board production line 901 and second board production line 902 using a moving wheeled platform. Accordingly, multiple tape feeders F can be collectively moved, and the efficiency of the movement work is increased. The operator may move feeder stand 1 to first board production line 901 and second board production line 902 without using the moving wheeled platform.

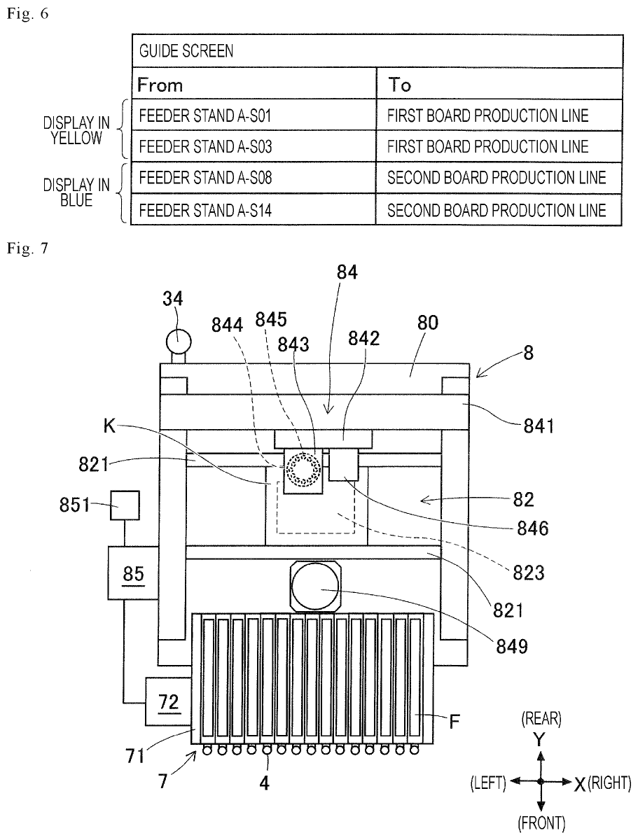

Furthermore, display control section 15 edits the display data representing the correspondence relationship between the storage positions of four tape feeders F to be moved and the movement destination device, and transmits the display data to screen display device 19. Screen display device 19 which has received the display data displays the correspondence relationship described above as illustrated in FIG. 6 by using the color assigned to each of the board production lines. In the screen display example of FIG. 6, “From” indicating a movement source is displayed on the left side of the second row, and “To” indicating the movement destination device is displayed on the right side. In addition, the display data of the third row and the fourth row whose movement destination is first board production line 901 is displayed in yellow, and the display data of the fifth row and the sixth row whose movement destination is second board production line 902 is displayed in blue.

By using screen display device 19 including the mobile terminal, the operator can recognize that the movement work of tape feeder F is requested even when the operator is away from feeder stand 1 or the board production line. In addition, even when storage side display section 11 and movement destination display sections (31 and 32) become invisible during the movement, the possibility that the movement destination of tape feeder F is mistaken is suppressed by the display using the corresponding color of screen display device 19.

Furthermore, for each of the multiple board production lines, it is possible to use an operation manner in which an operator in charge of the movement work of tape feeder F is fixedly determined. Accordingly, the operator can immediately determine whether he/she is in charge only by looking at the colors displayed on storage side display section 11 and movement destination display sections (3, 31, 32, and 33), which is very convenient.

In feeder movement assistance system 2 of the first embodiment, display control section 15 causes storage side display section 11 indicating the storage position of tape feeder F to be moved from feeder stand 1 and movement destination display sections (31, 32, and 33) provided in the movement destination device to which tape feeder F is to be moved to perform a display in the corresponding display manners. In other words, in feeder stand 1 of the embodiment, display control section 15 displays the display manner of storage side display section 11 indicating the storage position of tape feeder F to be moved in association with the display manner set in the movement destination device. The operator who has viewed the display can check the correspondence relationship between the position of the movement source of tape feeder F and the movement destination device, and thus can efficiently perform the movement work without making a mistake in the tape feeder, and without becoming lost in the movement destination. Accordingly, feeder movement assistance system 2 and feeder stand 1 can increase the efficiency of the movement work of tape feeder F.

### 5. Configuration Example of Component Mounter 8

Next, a configuration example of component mounter 8 using tape feeder F will be described with reference to FIG. 7. Component mounter 8 performs mounting work for mounting a component on board K. Component mounter 8 corresponds to a movement destination device serving as a candidate to which tape feeder F is to be moved. A direction from the left toward the right on the drawing surface in FIG. 7 in which board K is conveyed is an X axis direction, and a direction from the bottom (front side) toward the top (rear side) on the drawing surface is a Y axis direction. Component mounter 8 is formed by assembling board conveyance device 82, detachable component supply device 7, component transfer device 84, control device 85, movement destination display section 34, and the like to base 80.

Board conveyance device 82 includes a pair of guide rails 821, a pair of conveyance belts (not illustrated), clamp mechanism 823, and the like. The pair of guide rails 821 extends in the conveyance direction (X axis direction) across the center of the upper surface of base 80, and is assembled to base 80 in parallel with each other. The pair of conveyance belts rotate along guide rails 821 in a state where two parallel sides of board K are placed, and carry in board K to a work performing position in the vicinity of the center of base 80. Clamp mechanism 823 pushes up carried-in board K, clamps board K with guide rails 821, and positions board K. After the mounting work of a component by component transfer device 84 ends, clamp mechanism 823 releases board K, and the conveyance belts carry out board K to the outside of the device.

Detachable component supply device 7 is detachably provided in the front portion of base 80. Component supply device 7 supplies components to component transfer device 84. Component supply device 7 includes pallet 71, pallet control section 72, multiple position display sections 4, and multiple tape feeders F. Pallet 71 is formed in a substantially rectangular shape in plan view and is horizontally disposed. Pallet 71 is formed in a wheeled platform shape having a moving wheel and a moving steering wheel (not illustrated). Pallet 71 has the same configuration as slot 1F, positioning section 1H, and electrical connection section 1J of feeder stand 1A. Each of tape feeders F is inserted and set in each slot of pallet 71 from the front side.

Pallet control section 72 is disposed inside pallet 71. Pallet control section 72 is communicably connected to control device 85. Furthermore, pallet control section 72 is communicably connected to the feeder control section of set tape feeder F. Pallet control section 72 sends an operation command to the feeder control section based on a command from control device 85 to control the component supply operation of tape feeder F.

Multiple position display sections 4 are provided corresponding to each of the slots. Position display section 4 indicates a slot as an attachment position to which tape feeder F is attached. Each of position display sections 4 is disposed on the lower side of the slot on the front surface of pallet 71. Accordingly, the number of position display sections 4 matches the number of slots, in other words, is the number equal to the maximum number of attachable tape feeders F. As position display section 4, for example, a white monochromatic light source can be used. Position display section 4 is controlled by pallet control section 72.

Component transfer device 84 includes Y axis moving body 841, X axis moving body 842, mounting head 843, rotary tool 844, multiple suction nozzles 845, board recognition camera 846, component recognition camera 849, and the like. Y axis moving body 841 is formed of a member elongated in the X axis direction, and is driven by a Y direction drive mechanism to move in the Y axis direction. X axis moving body 842 is mounted on Y axis moving body 841, and is driven by an X direction drive mechanism to move in the X axis direction. Mounting head 843 is attached to a clamp mechanism (not illustrated) provided on a front surface of X axis moving body 842, and moves in two horizontal directions together with X axis moving body 842. Rotary tool 844 is rotatably provided below mounting head 843. Rotary tool 844 includes multiple (twelve in the example of FIG. 7) suction nozzles 845 at equal distances from the vertical central axis. Suction nozzle 845 is selectively supplied with the negative pressure air and the positive pressure air, and performs the pickup operation and the mounting operation of the component.

Board recognition camera 846 is provided on X axis moving body 842 alongside mounting head 843. Board recognition camera 846 is disposed such that an optical axis is directed downward, and captures an image of a position fiducial mark attached to board K from above. The acquired image data is subjected to image processing so that the work performing position of board K is accurately obtained. Component recognition camera 849 is provided on base 80 between board conveyance device 82 and component supply device 7. Component recognition camera 849 is disposed such that an optical axis is directed upward. Component recognition camera 849 captures an image of the component held by suction nozzle 845 from below and recognizes the component while mounting head 843 moves from component supply device 7 to board K. As a result, it is determined whether the type of the component is correct or incorrect, and the position and orientation of the component with respect to suction nozzle 845 are detected and reflected in the mounting work.

Control device 85 is assembled to base 80, and a disposition position thereof is not particularly limited. Control device 85 is configured using a computer device. Control device 85 controls board conveyance device 82, component supply device 7, and component transfer device 84 based on the mounting work data created for each type of board K. The mounting work data is data describing a detailed procedure of the mounting work, a method of performing the mounting work, or the like. Control device 85 includes display section 851 that displays the progress status of the mounting work, the occurrence status of an operation error, and the like.

Movement destination display section 34 is provided at the left rear of base 80. Similarly to movement destination display section 3 of the first embodiment, movement destination display section 34 is disposed at a high position using support pole 3P, and is easily viewed by the operator from a distance. Similarly to movement destination display section 3 of the first embodiment, a multicolor light source or a monochromatic light source lighting in one specific color can be applied to movement destination display section 34. Movement destination display section 34 is controlled by control device 85.

### 6. Feeder Movement Assistance System 2A of Second Embodiment

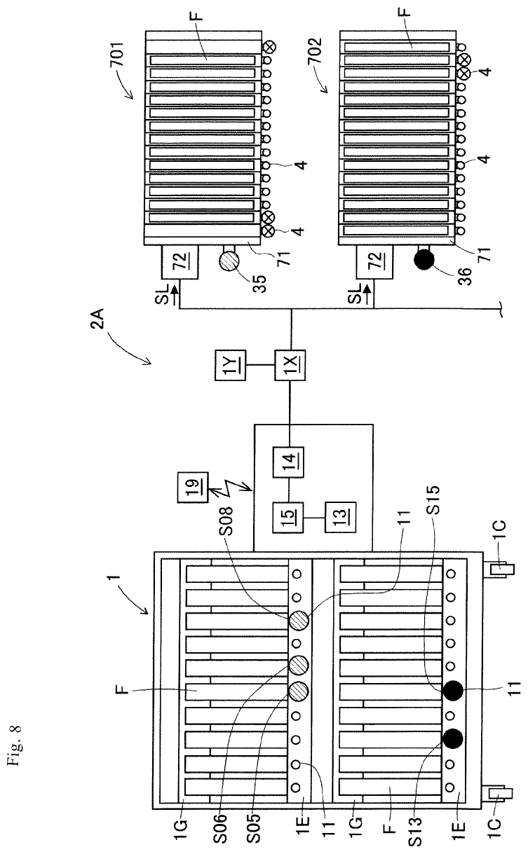

Next, a configuration and operation of feeder movement assistance system 2A of the second embodiment will be described with reference to FIG. 8. Feeder movement assistance system 2A is configured in an area of the external setup area. Feeder movement assistance system 2A includes feeder stand 1, movement destination display section 35 provided in first component supply device 701, movement destination display section 36 provided in second component supply device 702, position display section 4, work management device 1X, and the like.

First component supply device 701 and second component supply device 702 are removed from component mounter 8 and moved to the external setup area, or moved from the storage area to the external setup area. In first component supply device 701 and second component supply device 702, setup exchange operation of exchanging tape feeder F or work of attaching tape feeder F to an empty slot is performed. First component supply device 701 and second component supply device 702 correspond to multiple movement destination devices that are candidates to which tape feeder F is to be moved.

First component supply device 701 and second component supply device 702 are formed by adding movement destination display sections (35 and 36) to component supply device 7 described above. The positions of movement destination display sections (35 and 36) are not particularly limited as long as the positions are easy for the operator to view. Movement destination display sections (35 and 36) are multicolor light sources capable of selectively lighting seven colors. Although the colors of movement destination display sections (31, 32, and 33) are fixed in the first embodiment, the colors of movement destination display sections (35 and 36) are changeable in the second embodiment. This is because, since the number of component supply devices 7 used in the board production factory is larger than the number of lines of the board production line, when the color of movement destination display section 35 is fixed, multiple movement destination display sections 35 of the same color may exist in the system and cannot be distinguished.

By assigning different colors to the limited number of component supply devices 7 existing in the system, the possibility of not being distinguished is eliminated. In the following description, blue is assigned to movement destination display section 35 of first component supply device 701, and red is assigned to movement destination display section 36 of second component supply device 702. The assigned color is not changed through a period in which first component supply device 701 and second component supply device 702 remain in the system. Storage section 13 of feeder stand 1 stores different colors (display manners) from each other assigned to each component supply device.

As illustrated in FIG. 8, pallet control sections 72 of first component supply device 701 and second component supply device 702 are communicably connected to work management device 1X. Furthermore, work management device 1X is communicably connected to request reception section 14 of feeder stand 1. Work management device 1X holds tape feeder F to be removed from first component supply device 701 and second component supply device 702 and setup exchange data related to tape feeder F to be attached. The setup exchange data associates the positions of the slots of pallet 71 with any one of the codes (A), (B), and (C) related to tape feeder F to be attached and detached. The setup exchange data is one aspect of a movement request for moving tape feeder F stored in feeder stand 1 to the movement destination device.

Hereinafter, the operation of feeder movement assistance system 2A will be described using a case where the setup exchange operation of first component supply device 701 and second component supply device 702 is performed as an example. First, work management device 1X displays the contents of the setup exchange data on attached screen display section 1Y, and transmits the setup exchange data to pallet control section 72 and request reception section 14. Pallet control section 72 received the setup exchange data lights position display section 4 indicating the slot which is a target for the setup exchange operation of pallet 71.

In the example illustrated in FIG. 8, position display section 4 to be lit is illustrated using a large circle marked with an x for easy viewing, for convenience. As illustrated in the drawing, in first component supply device 701, position display sections 4 at the left end, the second from the left side, and the right end are lit. Tape feeder F is not attached to the left and right slots, and tape feeder F is attached to the second slot from the left side. As described above, there are a case where the slot which is a target for the setup exchange operation is empty and a case where tape feeder F is attached. In addition, in second component supply device 702, second and third position display sections 4 from the right side are lit.

Meanwhile, request reception section 14 which has received the setup exchange data transfers the contents of the setup exchange data to display control section 15. Display control section 15 obtains the storage position of tape feeder F to be moved based on the storage content of storage section 13 and the contents of the setup exchange data. That is, display control section 15 searches the storage content of storage section 13 using at least one code of (A), (B), and (C) included in the setup exchange data, obtains tape feeder F having the same code, and obtains the position of slot 1F in which tape feeder F is stored. Here, it is assumed that the positions related to first component supply device 701 are position S05, position 06, and position S08. In addition, it is also assumed that the positions related to second component supply device 702 are position S13 and position S15.

Display control section 15 causes storage side display section 11 indicating position S05, position 06, and position S08, and movement destination display section 35 provided in first component supply device 701 as the movement destination to perform a display in the corresponding display manners. The corresponding display manner means the display in blue assigned to first component supply device 701. That is, display control section 15 lights three storage side display sections 11 described above in blue. At the same time, display control section 15 transmits lighting request signal SL to pallet control section 72 of first component supply device 701 via work management device 1X. Pallet control section 72 which has received lighting request signal SL lights movement destination display section 35 in blue.

In addition, display control section 15 displays storage side display section 11 indicating position S13 and position S15, and movement destination display section 36 provided in second component supply device 702 as the movement destination in the corresponding display manners. The corresponding display manner means the display in red assigned to second component supply device 702. That is, display control section 15 lights two storage side display sections 11 described above in red. At the same time, display control section 15 transmits lighting request signal SL to pallet control section 72 of second component supply device 702 via work management device 1X. Pallet control section 72 which has received lighting request signal SL lights movement destination display section 36 in red.

In FIG. 8, for convenience, storage side display section 11 to be lit is illustrated using large circles for easy viewing. In addition, the lighting of storage side display section 11 and movement destination display section 35 in blue is indicated by oblique hatched circles, and the lighting of storage side display section 11 and movement destination display section 36 in red is indicated by black circles. The operator who views the lighting of each color can easily confirm the correspondence relationship between the position of slot 1F at which tape feeder F is pulled out and first component supply device 701 and second component supply device 702 which are movement destinations. Accordingly, the operator does not mistake the component supply device as the movement destination.

Position display section 4 displays the attachment position of tape feeder F (the slot of pallet 71) to facilitate the operator. However, even when position display section 4 displays the attachment position, position display section 4 does not display tape feeder F to be attached. Accordingly, the operator views screen display section 1Y of work management device 1X and confirms the correspondence relationship between multiple tape feeders F and the attachment positions thereof. As described above, in feeder movement assistance system 2B, the movement destination device of tape feeder F is guided using movement destination display sections (35 and 36), and the attachment position of tape feeder F is guided using screen display section 1Y. Accordingly, position display section 4 can be omitted.

### 7. Feeder Movement Assistance System 2B of Third Embodiment

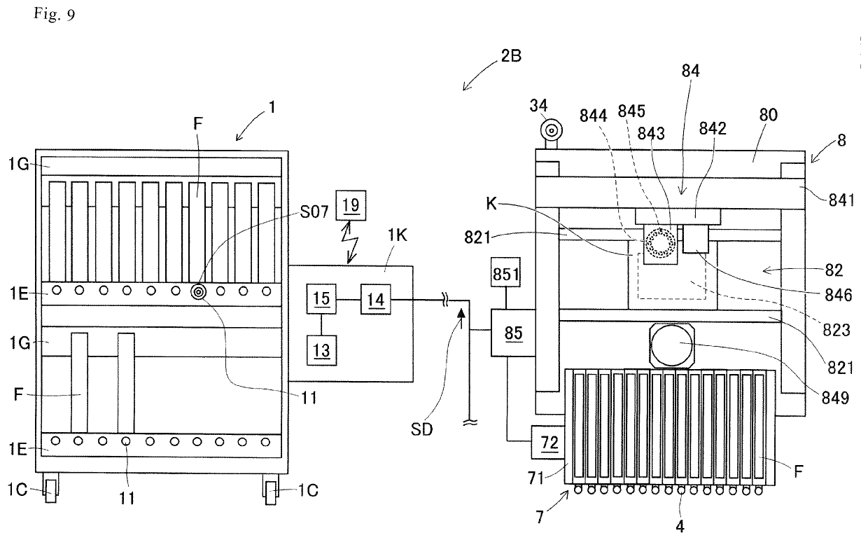

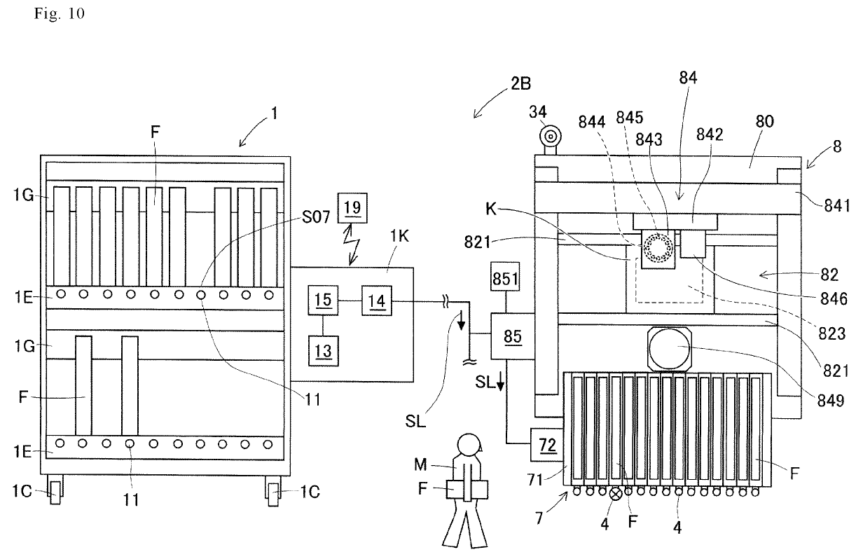

Next, a configuration and operation of feeder movement assistance system 2B of the third embodiment will be described with reference to FIGS. 9 and 10. Feeder movement assistance system 2B includes feeder stand 1, movement destination display section 34 provided in component mounter 8, position display section 4 provided in component supply device 7, and the like. Request reception section 14 of feeder stand 1 is communicably connected to control devices 85 of multiple component mounters 8. In FIG. 9, second and subsequent component mounters 8 are not illustrated.

When the component shortage occurs in any of tape feeders F as the mounting work of component mounter 8 progresses, control device 85 stores the position (slot) of tape feeder F and transmits movement request signal SD described above to request reception section 14. Request reception section 14 transfers the fact that movement request signal SD is received and the contents of movement request signal SD to display control section 15.

Display control section 15 first obtains the storage position of tape feeder F to be moved based on the storage content of storage section 13 and the contents of the movement request. That is, display control section 15 searches the storage content of storage section 13 using at least one code of (A), (B), and (C) included in movement request signal SD, obtains tape feeder F having the same code, and obtains the position of slot 1F in which tape feeder F is stored. Here, it is assumed that the position is position S07.

Next, display control section 15 causes storage side display section 11 indicating position S07, and movement destination display section 34 provided in component mounter 8 as the movement destination to perform a display in the corresponding display manners. The corresponding display manner means that display is performed in the same color, and hereinafter, display is performed in yellow. That is, display control section 15 lights storage side display section 11 indicating position S07 in yellow. At the same time, display control section 15 transmits lighting request signal SL to control device 85. Control device 85 which has received lighting request signal SL lights movement destination display section 34 in yellow.

In FIG. 9, for convenience, storage side display section 11 to be lit is illustrated using large circles for easy viewing. In addition, the lighting of storage side display section 11 and movement destination display section 34 in yellow are indicated by triple circles. The operator who views the lighting in yellow can easily confirm the correspondence relationship between position S07 at which tape feeder F is pulled out and component mounter 8 which is the movement destination. The operator pulls out and holds tape feeder F from slot 1F at position S07. Furthermore, the operator is guided to movement destination display section 34 which is lit, and moves toward component mounter 8. During the movement, the operator cannot directly view position display section 4.

Here, the operation proceeds to the latter half of the operation illustrated in FIG. 10. Display control section 15 displays position display section 4 after the specific condition is satisfied. In practice, display control section 15 transmits lighting request signal SL to control device 85 after the specific condition is satisfied, and pallet control section 72 which has received lighting request signal SL lights position display section 4. The specific condition is a condition for determining that the timing of inserting tape feeder F into the slot of pallet 71 approaches, and is any one of the following (D), (E), and (F).
(D) Condition under which tape feeder F is taken out from feeder stand 1
(E) Condition in which tape feeder F approaches to the predetermined distance with respect to movement destination display section 34
(F) Condition under which the operator issues a command to display position display section 4

Condition (D) described above is automatically determined when stand control section 1K cannot communicate with tape feeder F. In addition, condition (E) is determined by a configuration in which the GPS function is added to tape feeder F, and the position information is transmitted to display control section 15. Alternatively, condition (E) is determined when wireless communication using weak radio waves is tried between tape feeder F and component mounter 8 and wireless communication becomes possible while approaching the predetermined distance. Furthermore, condition (F) is determined when the operator transmits a command to display control section 15 using screen display device 19 including a mobile terminal.

In the example of FIG. 10, tape feeder F in the fourth slot from the left side runs out of components. Control device 85 which has received lighting request signal SL transfers lighting request signal SL to pallet control section 72. Pallet control section 72 which has received lighting request signal SL lights position display section 4 corresponding to the position of tape feeder F in which the component runs out. In FIG. 10, position display section 4 to be lit is indicated by a large circle marked with an x for convenience. When operator M approaches component mounter 8 while being guided by movement destination display section 34, operator M can directly view the lighting of position display section 4. Accordingly, operator M can remove tape feeder F in which the component runs out and attach tape feeder F moved from feeder stand 1 without making a mistake in the attachment position in addition to not making a mistake in the movement destination device.

Meanwhile, in feeder stand 1, after tape feeder F is pulled out, storage side display section 11 indicating position S07 is extinguished. As a result, another tape feeder F can be stored in slot 1F at position S07. As described above, control for limiting the lighting time of position display section 4 and storage side display section 11 can contribute to power saving by omitting meaningless lighting (display) which is invisible to operator M. In addition, since there is no unnecessary lighting, misunderstanding or the like by another operator is suppressed.

### 8. Modification and Application of Embodiment

The first to third embodiments can be configured to overlap each other. That is, request reception section 14 of feeder stand 1 can be simultaneously communicably connected to line management device 98, work management device 1X, and control device 85. In addition, display control section 15 can simultaneously control movement destination display sections (3, 31, 32, 33, 34, 35, and 36) of various movement destination devices and position display section 4. Furthermore, in the second and third embodiments, instead of position display section 4, a display section provided in tape feeder F and controlled by pallet control section 72 may be used. However, in this aspect, indicating an empty slot of pallet 71 is omitted.

In addition, in the first embodiment, the blinking manner of storage side display section 11 and movement destination display section 3 is used to increase the number of types of display manners, but may be used to indicate the level of urgency. For example, in a modification example of the third embodiment, in a case where a high-urgency movement request is generated due to component shortage of tape feeder F, display control section 15 causes storage side display section 11 and movement destination display section 34 to be continuously lit in the same color. Furthermore, in a case where a low-urgency movement request is generated due to the component shortage notice in which the number of remaining components of tape feeder F is equal to or less than the predetermined number, display control section 15 causes storage side display section 11 and movement destination display section 34 to blink in the same color. Accordingly, the operator can prioritize the movement work of tape feeder F indicated by continuous lighting, postpone the movement work of tape feeder F indicated by blinking, and optimize the order of the movement work. In addition, various modifications and applications can also be made in the first to third embodiments.

### REFERENCE SIGNS LIST

1, 1A: Feeder stand, 11: Storage side display section, 13: Storage section, 14: Request reception section, 15: Display control section, 19: Screen display device, 1E: Shelf plate, 1F: Slot, 1K: Stand control section, 1X: Work management device, 2, 2A, 2B: Feeder movement assistance system, 3, 31, 32, 33, 34, 35, 36: Movement destination display section, 4: Position display section, 7: Component supply device, 701: First component supply device, 702: Second component supply device, 71: Pallet, 72: Pallet control section, 8: Component mounter, 82: Board conveyance device, 84: Component transfer device, 85: Control device, 9: Board production line, 93: First component mounter, 94: Second component mounter, 95: Third component mounter, 96: Feeder buffer, 97: Feeder conveyance device, 98: Line management device, F: Tape feeder, SD: Movement request signal, SL: Lighting request signal

1. A feeder movement assistance system comprising:
multiple storage side display sections disposed corresponding to multiple storage positions of a feeder stand storing multiple tape feeders, respectively and configured to perform a display indicating the storage position in a display manner selected from multiple display manners;
a storage section configured to store the tape feeder stored in the feeder stand and the storage position in association with each other;
multiple movement destination display sections provided in multiple movement destination devices as candidates to which the tape feeder is to be moved, respectively and configured to perform a display in the display manners which are different from each other; and
a display control section configured to cause the storage side display section indicating the storage position of the tape feeder to be moved and the movement destination display section provided in the movement destination device to which the tape feeder is to be moved to perform a display in a corresponding display manner, based on a storage content of the storage section and a content of a movement request, in a case where the movement request for moving the tape feeder stored in the feeder stand to any of the multiple movement destination devices is generated.

2. The feeder movement assistance system according to claim 1, wherein
the storage side display section is a light source capable of selectively lighting in any one of multiple colors as the multiple display manners, and
the movement destination display section is a light source capable of lighting a specific color or a placard configured to display a specific color.

3. The feeder movement assistance system according to claim 2, wherein
the storage side display section and the movement destination display section use a color and a blinking manner of the light source in combination as the display manner.

4. The feeder movement assistance system according to claim 1, wherein
the display control section cause the multiple storage side display sections and one or more movement destination display sections to simultaneously perform a display so as to correspond to the multiple tape feeders to be moved.

5. The feeder movement assistance system according claim 1, further comprising:
a screen display device configured to display a correspondence relationship between the storage position of the tape feeder to be moved and the movement destination device on a screen using the display manner corresponding to the storage side display section and the movement destination display section.

6. The feeder movement assistance system according to claim 1, wherein
the multiple movement destination devices include at least one or more of a component mounter equipped with the tape feeder, a board production line including the component mounter, and a detachable component supply device detachably provided in the component mounter in a state where the tape feeder is equipped.

7. The feeder movement assistance system according to claim 6, wherein
the movement destination device is the board production line including the component mounter, a feeder buffer configured to temporarily hold the moved tape feeder, and a feeder conveyance device configured to convey the tape feeder between the component mounter and the feeder buffer.

8. The feeder movement assistance system according to claim 6, wherein
the movement destination device is the component mounter having multiple attachment positions to which the tape feeders can be attached, respectively, or the board production line including the component mounter,
the feeder movement assistance system further includes multiple position display sections disposed corresponding to the multiple attachment positions, respectively and configured to perform a display indicating the attachment positions, and
the display control section causes the storage side display section indicating the storage position of the tape feeder to be moved, the movement destination display section provided in the component mounter or in the board production line to which the tape feeder is to be moved, and the position display section indicating the attachment position to which the moved tape feeder is attached to perform a display.

9. The feeder movement assistance system according to claim 8, wherein
in a case where the movement request is generated, the display control section causes the storage side display section and the movement destination display section to perform a display and causes the position display section to perform a display after a specific condition is satisfied.

10. The feeder movement assistance system according to claim 9, wherein
the specific condition includes any one of a condition in which the tape feeder is taken out from the feeder stand, a condition in which the tape feeder approaches to the predetermined distance with respect to the movement destination display section, and a condition in which an operator issues a command to cause the position display section to perform a display.

11. The feeder movement assistance system according to claim 1, wherein
an operator who moves the tape feeder is determined for the multiple movement destination devices, respectively.

12. A feeder stand used in the feeder movement assistance system according to claim 1.

13. A feeder stand comprising:
multiple storage positions where tape feeders are stored, respectively;
multiple storage side display sections disposed corresponding to the multiple storage positions, respectively and configured to perform a display indicating the storage position in a display manner selected from multiple display manners;
a storage section configured to store a correspondence relationship between the stored tape feeder and the storage position, and the display manners different from each other and set in multiple movement destination devices as candidates to which the tape feeder is to be moved, respectively; and
a display control section configured to display the display manner of the storage side display section indicating the storage position of the tape feeder to be moved in association with the display manner set in the movement destination device to which the tape feeder is to be moved, based on a storage content of the storage section and a content of a movement request, in a case where the movement request for moving the stored tape feeder to any one of the multiple movement destination devices is generated.
